(19) United States
(12) Patent Application Publication
(10) Pub. No.: US 2008/0211552 A1
(43) Pub. Date: Sep. 4, 2008

(54) Controllable synchronous rectifier

(76) Inventor: Chao-Cheng Lu, Taipei (TW)

Correspondence Address: CHAO-CHENG LU;NO.4-4, Alley 27, Lane 143, Chun Kung Road, Taipei, 11614, TW

(21) Appl. No.: 11/712,349

(22) Filed: Mar. 1, 2007

(51) Int. Cl. H03L 7/00; H02M 7/217

(52) U.S. Cl. 327/143; 327/194; 363/127

(57) ABSTRACT

The present controllable synchronous rectifier employs a Lus semiconductor to set synchronous rectification action in quadrant 1 of output characteristics of the conventional power MOSFETs. By controlling the voltage level of the gate-source voltage, the drain current can be controlled in the synchronous rectifier. Further, in combination with a protect opposite circuit to transfer a sinusoidal wave power supply or pulse power supply to a direct current power output, the synchronous rectifier is an indispensable high efficiency rectifier in the industry.

### BACKGROUND OF THE INVENTION

1. Field of the Invention

The present invention relates to power metal oxide semiconductor field effect transistors (hereinafter referred to as “power MOSFETs”), and more particularly, to power MOSFETs that a conventional static shielding diode (hereinafter referred to as “SSD”), or body diode, or intrinsic diode is replaced with creative structure. According to the present invention, the conventional SSD can be changed to an SSD or Schottky diode or Zener diode with an opposite polarity, or changed to two reversely connected Schottky diodes, two reversely connected Zener diodes, two reversely connected fast diodes, or changed to a four-layer device such as DIAC or TRIAC, which allows it to keep its original functions, and needs only to consider the amount of reverse voltage to adopt appropriate semiconductor working voltage to achieve the objectives of the present invention. Referring to FIG. 2(E) and FIG. 2(F); the reverse working voltage is tantamount to Zener voltage, and can be set according to needs. The set Zener voltage should be higher than the direct current output voltage of the present invention in practice, which is similar to that the SSD voltage of the conventional power MOSFETs should be higher than the input voltage in the alternative current side, and the Zener voltage of the reversely connected Zener diodes is higher than the direct current output voltage. According to this design principle, the present invention can use one single power MOSFETs in combination with auxiliary circuits to achieve the functions of half wave rectification, or use two power MOSFETs in combination with the auxiliary circuits to achieve the functions of full wave rectification. In both situations, the functions can be performed in quadrant 1 of output characteristics of the conventional power MOSFETs. By controlling the voltage level of the gate-source voltage, the drain current can be controlled to meet the rectifier requirements and remain safe. Further, by combining with a protect opposite circuit to transfer a sinusoidal wave power source or pulse power source to a direct current power output, the rectifier can perform the synchronous rectification and thus achieve the goal of high efficiency rectification. It is noticed that the power MOSFETs in accordance with the present invention also include power junction field effect transistors (hereinafter referred to as “JFETs”) that employ the circuit features of the present invention. That the drain and source of the power JFETs are connected with the circuit features of the present invention is also covered by the present invention.

2. Description of Related Art

FIG. 3 illustrates a conventional single-ended forward synchronous rectifier. From the figure, it can be known that, during rectification, V1 is for rectification and V2 is for continuing current. The operation principle is that, during a positive half period of the secondary voltage Us, V1 turns on, V2 turns off, and V1 is used to rectify; during negative half period of the secondary voltage Us, V1 turns off, V2 turns on, and V2 is used to continue the current. The power loss of the synchronous rectifier mainly includes turn-on losses of V1, V2 and gate drive loss. Therefore, the convention synchronous rectifier has the following shortcomings:

1. As to loss, the loss in continuing the current results in a decrease in synchronous rectification power.

2. As to material cost, EMFETs are required for continuing the current in synchronous rectification, which increases the manufacturing cost.

### SUMMARY OF THE INVENTION

The present invention is directed to meeting the semiconductor need of high efficiency rectification and providing a direct current power supply device to perform rectification.

A first objective of the present invention is to provide a rectifier which employs a Lus semiconductor as a main switch, which is a switch reversing the polarity of an intrinsic diode, and employs low capacitance drain as a high frequency voltage input end, and which can be used with high frequency power source to address the problem that, conventionally, the high frequency voltage input end must be the source.

A second objective of the present invention is to provide a rectifier which employs a Lus semiconductor as a main switch, employs a voltage comparison integrated circuit of a protect opposite current to supply the gate-source voltage, and employs an independent auxiliary direct current power supply to supply power to the protect opposite circuit, therefore, and can eliminate the drawback of gate burn caused by a surge voltage.

A third objective of the present invention is to set an auxiliary direct current power source for the protect opposite circuit and combine with the Lus semiconductor to output a stable gate-source voltage to achieve the goal of controlling drain current.

A fourth objective of the present invention is to set a protect opposite circuit, when the source voltage is higher than the drain voltage, the gate of the Lus semiconductor is at zero voltage level to achieve an opposite current protection function, without being affected by turn-on delay time or turn-off delay time of the high frequency power supply which causes the opposite current.

A fifth objective of the present invention is to provide preferred embodiments of hardware circuits to prove the present invention can achieve its objectives and functions and can be practiced according to these embodiments.

To address the problem in rectification and voltage regulation of conventional high efficiency direct current power supply, the present invention has the following features:

1. A sinusoidal wave power source or a pulse power source or a nonsinusoidal wave power source is adopted as a high frequency power source, and coupled with a high frequency transformer primary side.

2. High frequency transformer is a power transfer device, which transfers the power of a high frequency power source circuit from a primary coil to a secondary coil of the transformer, and has not only power transfer function, but also isolation function.

3. The Lus semiconductor is adopted to replace the conventional power MOSFETs or power JFETs. During a fabrication process thereof, the parasitic diode or intrinsic diode is changed to diode with opposite polarity, that is, circuit features of the Lus semiconductor as shown in FIG. 2 are formed between the drain and source of the power MOSFETs or power JFETs during the fabrication process thereof or externally connected between the drain and source. The rectifier can be used in PFM circuits, PWM circuits to perform rectification to eliminate the drawbacks of the conventional power MOSFETs or power JFETs.

4. The direct current output circuit is controlled by the Lus semiconductor, and has a filter circuit and a direct current output end to ensure the present invention to provide a direct current power supply for a load.

5. The protect opposite circuit is used to prevent the source voltage from being higher than the drain voltage so as not to generate an opposite current. The voltage comparison circuit formed by a voltage comparison integrated circuit performs the function of opposite current prevention.

6. The independent auxiliary direct current power supply is dedicated to supply a gate-source voltage of the Lus semiconductor, and is isolated apart from the secondary coil of the high frequency transformer of the Lus semiconductor, but is another secondary coil commonly belonging to the high frequency transformer.

Therefore, to address the above conventional problems and propose a novel solution employing the Lus semiconductor and the protect opposite circuit to design a high efficiency power supply system to overcome the conventional shortcomings.

### BRIEF DESCRIPTION OF THE DRAWINGS

FIG. 1 is a view showing structures of N-Channel and P-Channel of Lus semiconductor.

FIG. 2 is a view showing circuit feature structures between drain and source of a Lus semiconductor.

FIG. 3 is a view showing a circuit diagram of a prior art single-ended forward synchronous rectifier.

FIG. 4 is a schematic view showing a half wave synchronous rectifier constituted by a Lus semiconductor and a protect opposite circuit, and output characteristics thereof.

FIG. 5 is a view showing a circuit diagram of an auxiliary direct current power supply for a voltage comparison circuit of the Lus semiconductor and the protect opposite circuit.

FIG. 6 is a schematic view showing a double-ended Lus semiconductor synchronous rectifier and output characteristics thereof.

### DETAILED DESCRIPTION OF THE PREFERRED EMBODIMENTS

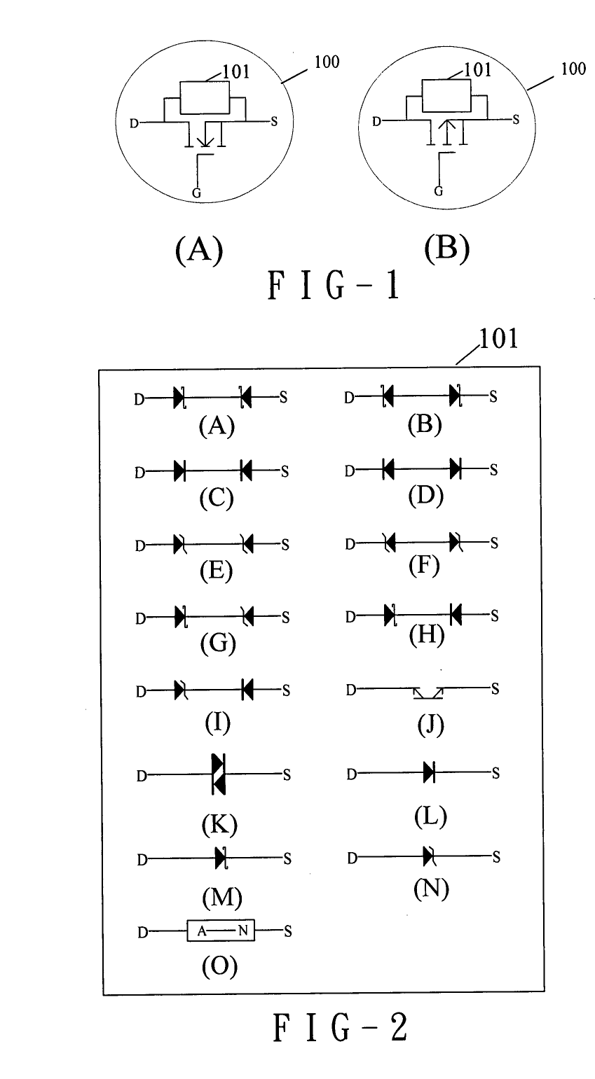

FIG. 1(A) illustrates an N-Channel power MOSFETs of a Lus semiconductor 100 in accordance with the present invention, and FIG. 1(B) illustrates the structure of a P-Channel power MOSFETs. FIG. 2 illustrates circuit features 101 coupled between a drain and a source of the power MOSFETs of FIG. 1 in accordance with the present invention. FIG. 2(A) and FIG. 2(B) illustrate two reversely series-connected Schottky diodes being connected between the drain and source of the power MOSFETs; FIG. 2(C) and FIG. 2(D) illustrate two reversely series-connected static shielding diodes (hereinafter referred to as “SSDs”) being connected between the drain and source of the power MOSFETs; FIG. 2(E) and FIG. 2(F) illustrate two reversely series-connected Zener diodes being connected between the drain and source of the power MOSFETs; FIG. 2(G) illustrates reversely series-connected Schottky diode and Zener diode being connected between the drain and source of the power MOSFETs; FIG. 2(H) illustrates reversely series-connected Schottky diode and SSD being connected between the drain and source of the power MOSFETs; FIG. 2(I) illustrates reversely series-connected Zener diode and SSD being connected between the drain and source of the power MOSFETs; FIG. 2(J) illustrates a DIAC of a four-layer semiconductor being connected between the drain and source of the power MOSFETs; and FIG. 2(K) illustrates a TRIAC being connected between the drain and source of the power MOSFETs. The foregoing circuit feature components illustrated in FIGS. 2(A) through 2(K) may each be disposed between the drain and source of the power MOSFETs to form the Lus semiconductor 100. Furthermore, all the circuit features 101 illustrated in FIGS. 2(A) through 2(K) can make synchronous rectifying operation performed in Quadrant 1 of the output characteristics, thus achieving high efficiency rectifying functions. Circuit features illustrated in FIGS. 2(L), 2(M) and 2(N) are diode features that can make output characteristics in Quadrant 1. FIG. 2(O) illustrates circuit features formed by combinations of the semiconductor devices of FIGS. 2(A) through 2(N) in parallel or series, or external Snubber circuits being connected between the drain and source, which are set according to application circuit needs and the present invention is not limited to these circuit features. Circuit features of power JFETs are the same as those of above power MOSFETs, and will not be described herein.

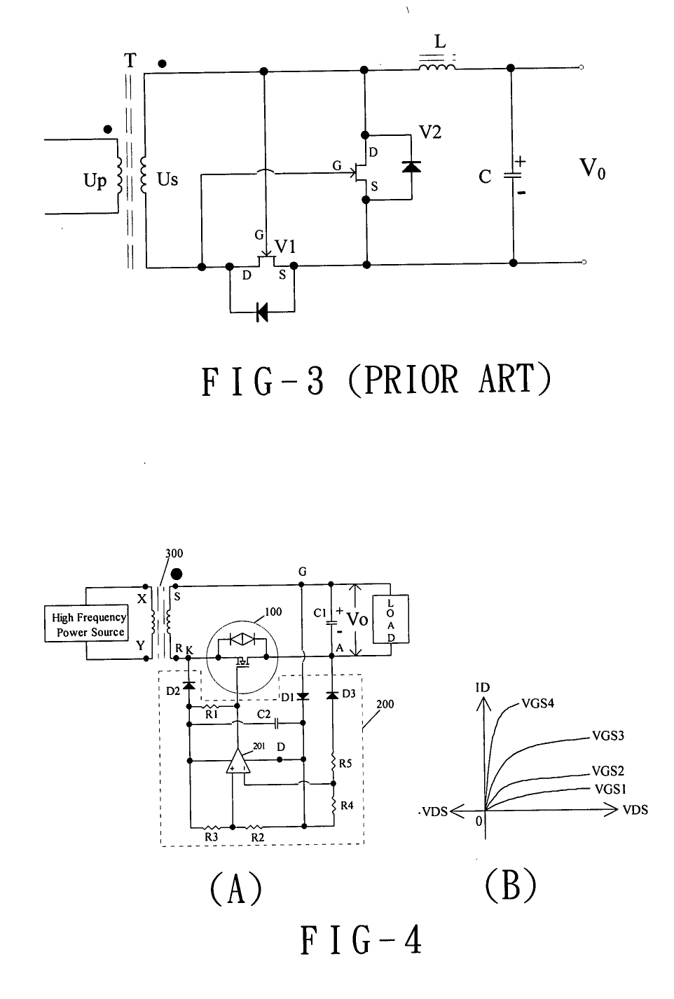

Referring to FIG. 3, a prior art single-ended forward synchronous rectifier is illustrated, the operation principle of which has been described in the Description of Related Art section and will not be described herein.

Referring to FIG. 4, a half wave synchronous rectifier in accordance with the present invention constituted of the Lus semiconductor 100 and a protect opposite circuit 200, and output characteristics thereof are illustrated. From FIG. 4(A), it can be seen that, when a voltage of an S terminal of a high frequency transformer 300 is a positive voltage, the current thereof flows from the S terminal through a filter capacitor C1 and a LOAD to the drain of the Lus semiconductor 100. In this situation, output of a voltage comparison circuit 201 of the protect opposite circuit 200 is a positive voltage due to that a voltage between G and K terminals is higher than a voltage between G and A terminals, so a voltage of a noninverter end of the voltage comparison circuit 201 is higher than a voltage of an inverter end of the voltage comparison circuit 201. Accordingly, a gate of the Lus semiconductor 100 is applied with a positive voltage to turn on the drain and source. In this situation, the drain is used as an input end of a high frequency voltage, which is different from the traditional synchronous rectifying operation wherein the source is the input end of the high frequency voltage, and a half-period of the synchronous rectifying operation is then achieved. The power supply terminal D of the voltage comparison circuit 201 is supplied with power by a positive voltage of G terminal which is rectified through diode D1 and then supplies the power via a filter capacitor C2. R1 is gate resistance, and a voltage between two ends of R1 is the gate-source voltage. D2 and D3 are unilateral diodes. R2 and R3 are voltage divider resistance of the noninverter end. R4 and R5 are voltage divider resistance of the inverter end. When a voltage of R terminal is a positive voltage, the voltage of the noninverter end is a zero voltage due to isolation by the unilateral diodes D1, D2, so that the output voltage of the voltage comparison circuit 201 is a zero voltage. Accordingly, the gate of the Lus semiconductor 100 has no voltage output, rather the drain and source of the Lus semiconductor 100 turn to OFF state. The above description introduces the status of a pulse power supply at the R, S terminals of the high frequency transformer 300. When the voltage of the S terminal is at positive half-period of sinusoidal wave, the phase of the sinusoidal wave is from 0° to 90°, that is, the sinusoidal wave voltage varies from 0 to a maximum value. In this situation, the voltage of the noninverter end of the voltage comparison circuit 201 is higher than the voltage of the inverter end, and the Lus semiconductor 100 turns to ON state. When the phase of the sinusoidal wave is from 90° to 180°, the sinusoidal wave voltage varies from the maximum value to zero voltage. At this time, if the load of the direct current output circuit is a light load, the voltage between two ends of the filter capacitor C1 may be higher than the voltage between S and R terminals, and the voltage of the inverter end is higher than the voltage of the noninverter end, which causes the Lus semiconductor 100 to turn to OFF state, thus achieving the function of protecting opposite current. When the voltage of the R terminal is at positive half-period of sinusoidal wave, the Lus semiconductor 100 is in the OFF state due to the isolation by the unilateral diodes D2 and D3. From the operation principle described above, it can be known that the present invention can be implemented in both sinusoidal wave power source and pulse power source to perform rectification function, from the operation principle described above, the nonsinusoidal wave power source same as sinusoidal wave power source, and thus is not described. Referring to FIG. 4(B), which illustrates output characteristics of the semiconductor, from FIG. 4(B), it can be seen that the drain current ID varies with different gate-source voltages such as VGS1, VGS2, VGS3 and VGS4. Therefore, as long as the D terminal is supplied with different power voltages, the voltage comparison circuit 201 can output different output voltages, that is, different gate-source voltages, to obtain different drain current ID. Thus, the present invention is a controllable synchronous rectifier that has many advantages. If charged with a constant current, the filter capacitor C1 can be protected. The Lus semiconductor 100 and the protect opposite circuit 300 are featured by three connect terminals A, K, G for external connection.

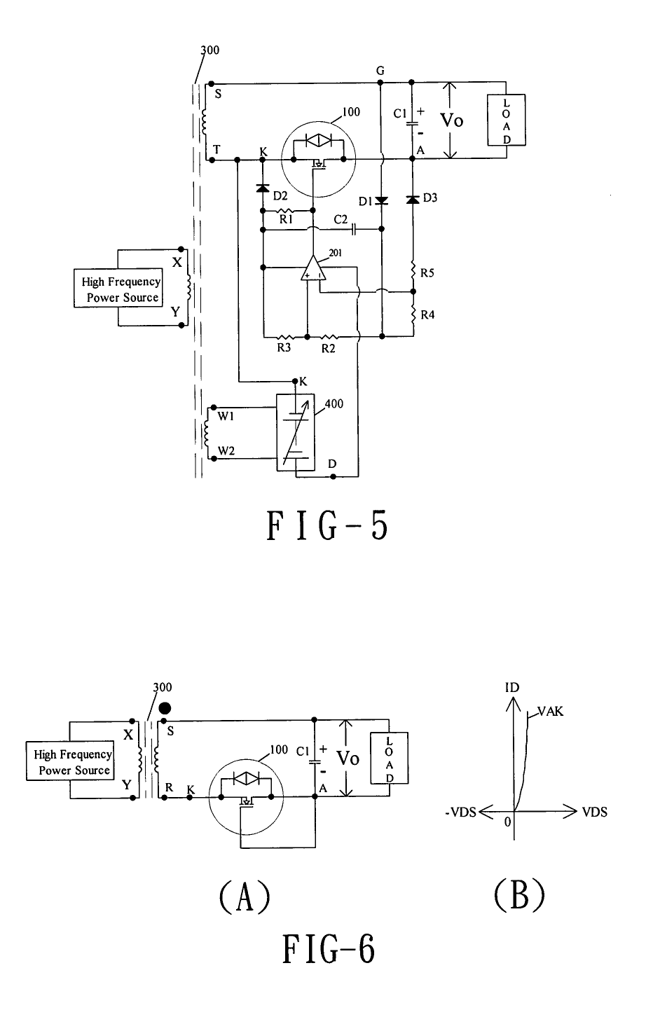

Referring to FIG. 5, a circuit diagram of an auxiliary direct current power supply 400 for the voltage comparison circuit 201 of the Lus semiconductor 100 and the protect opposite circuit 200 is illustrated. From the figure, it can seen that except the auxiliary direct current power supply 400, the rest of the circuits are the same as those of FIG. 4(A), and the output characteristics of the rest circuits are also the same as those of FIG. 4(B). Therefore, the auxiliary direct current power supply 400 is illustrated as a symbol for a variable voltage, which means supplying different external voltages can get different gate-source voltage outputs, and can then control generation of different drain currents, thereby achieving the goal of controlling the amount of the drain current. The feature of the auxiliary direct current power supply 400 is that it is an independent power supply which can gain high frequency voltage from two ends W1, W2 of a secondary coil of the high frequency transformer 300. The auxiliary direct current power supply 400 consists of a rectifier and voltage stabilizer that meets the need of various different voltage outputs. Because of the independent power supply feature, the auxiliary direct current power supply 400 can also be supplied by other alternating current power sources or direct current power sources other than the high frequency transformer 300, and thus the present invention is not limited to a particular embodiment of the auxiliary direct current power supply 400. The operation principle is the same as that in FIG. 4(A) and thus is not described herein. The positive voltage supply end of the voltage comparison circuit 201 is D terminal, and is connected to positive electricity carries of the auxiliary direct current power supply 400.

Referring to FIG. 6, a double-ended Lus semiconductor 100 and output characteristics thereof are illustrated. From FIG. 6(A), it can be known that, during fabrication process of the Lus semiconductor 100, the gate can be coupled to the drain to form the double-ended Lus semiconductor 100, or in use, the gate and drain of the original three-terminal Lus semiconductor 100 can also be coupled together to form the double-ended Lus semiconductor 100. The operation principle of the double-ended Lus semiconductor 100 is that when the voltage of the S terminal of the high frequency transformer 300 is a positive voltage, the current thereof flows through the filter capacitor C1 and the LOAD to the A terminal of the double-ended Lus semiconductor 100, and the gate and drain have a same voltage, making the AK terminals in an ON state, thereby achieving the half wave rectifying function; when the voltage of the R terminal is a positive voltage, because the voltage of the source is higher than the voltage of the gate and drain, the KA terminals are in an OFF state. The double-ended Lus semiconductor 100 is rather simple in use, but cannot control the amount of drain current, the rectifier is configurable to form a half wave rectifier or a full wave rectifier or a multivoltage rectifier; from FIG. 6(B), it can be seen that the gate and the drain are coupled to each other to form A joint, and the source is K joint, thus the voltage there between is VAK, and the output characteristics are also in Quadrant 1.

In summary, it should be understood that the controllable synchronous rectifier in accordance with the present invention is the world's first to employ the Lus semiconductor 100 as a main switch to develop a system circuit having functions of high efficiency rectification, opposite current protection and variable voltage output. The controllable synchronous rectifier employs a sinusoidal wave power source or a pulse power source or a nonsinusoidal wave power source to the high frequency transformer 300, and employs the Lus semiconductor 100 as the main switch to achieve the goal of allowing the high frequency and high voltage power supply to perform synchronous rectification. At the same time, the controllable synchronous rectifier includes the protect opposite circuit 200 to prevent the drawback that the opposite current flows from the direct current output side to the high frequency transformer secondary side to cause a short circuit. Due to the utilization of the Lus semiconductor 100, the controllable synchronous rectifier still employs the low on-state-resistance of the power MOSFETs or power JFETs, inverts the intrinsic diode of the power MOSFETs or power JFETs and replaces it with the circuit features to achieve low voltage drop, low loss and high efficiency rectification. Therefore, the present invention can be utilized in various electronic devices where a high frequency electrical energy is transformed to a direct current power supply, such as personal computers, notebook computers, TV sets, refrigerators, air conditioners, and the like, which can all obtain a small, thin and light-weighted direct current power supply apparatus with a high efficiency.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A controllable rectifier adapted for being used at a high frequency transformer secondary side, comprising:
a Lus semiconductor comprising a parasitic circuit feature formed between a drain and a source of a power MOSFETs or a power JFETs during a fabrication process thereof, or an external circuit feature connected between the drain and the source, the parasitic or external circuit feature having rectifying function;
a protect opposite circuit comprising a voltage comparison circuit and passive components, the voltage comparison circuit configured to output voltage to a gate and the source of the Lus semiconductor; and
a filter capacitor coupled to the Lus semiconductor.

2. The controllable rectifier in accordance with claim 1, wherein the parasitic circuit feature of the Lus semiconductor formed during the fabrication process thereof or the external circuit feature is selected from the group consisting of at least two Schottky diodes reversely connected in series, at least two static shielding diodes reversely connected in series, at least two Zener diodes reversely connected in series, at least one Schottky diode and at least one Zener diode reversely connected in series, at least one Schottky diode and at least one static shielding diode reversely connected in series, at least one Zener diode and at least one static shielding diode reversely connected in series, combinations of the foregoing semiconductor devices in series or parallel, and external Snubber circuit, the term reversely connected in series referring to that P type ends are connected with each other or N type ends are connected with each other;
the P type ends of the circuit feature diode devices coupled to the drain of the power MOSFETs, N type ends coupled to the source of the power MOSFETs, the diode devices referring to fast diode, Schottky diode or Zener diode, but a P-channel power MOSFETs being connected with polarities reverse to that of aforesaid connection.

3. The controllable rectifier in accordance with claim 1, wherein the voltage comparison circuit is supplied with power by one or multiple independent auxiliary direct current power sources or by one or multiple dependent power source.

4. The controllable rectifier in accordance with claim 1, wherein the high frequency transformer primary side is used in a sinusoidal wave power source or a pulse power source or a nonsinusoidal wave power source.

5. The controllable rectifier in accordance with claim 1, 2, 3 or 4, wherein the rectifier is configurable to form a half wave rectifier or a full wave rectifier.

6. A rectifier adapted for being used at a high frequency transformer secondary side, comprising:
a Lus semiconductor comprising an intrinsic circuit feature formed between a drain and a source of a power MOSFETs or a power JFETs during a fabrication process thereof, or an external circuit feature connected between the drain and the source, having a gate thereof coupled to the drain and a filter capacitor, and having rectification and operation conducted in Quadrant 1; and
a filter capacitor coupled to the Lus semiconductor.

7. The rectifier in accordance with claim 6, wherein the gate and drain are coupled together during the fabrication process thereof and packaged within the Lus semiconductor, or externally coupled together to form two terminals.

8. The rectifier in accordance with claim 6, wherein the parasitic circuit feature of the Lus semiconductor formed during the fabrication process thereof or the external circuit feature is selected from the group consisting of at least two Schottky diodes reversely connected in series, at least two static shielding diodes reversely connected in series, at least two Zener diodes reversely connected in series, at least one Schottky diode and at least one Zener diode reversely connected in series, at least one Schottky diode and at least one static shielding diode reversely connected in series, at least one Zener diode and at least one static shielding diode reversely connected in series, combinations of the foregoing semiconductor devices in series or parallel, and an external Snubber circuit, the term reversely connected in series referring to that P type ends are connected with each other or N type ends are connected with each other;
the P type ends of the circuit feature diode devices coupled to the drain of the power MOSFETs, N type ends coupled to the source of the power MOSFETs, the diode devices referring to fast diode, Schottky diode or Zener diode, but a P-channel power MOSFETs being connected with polarities reverse to that of aforesaid connection

9. The rectifier in accordance with claim 6, wherein the high frequency transformer primary side is used in a sinusoidal wave power source or a pulse power source or a nonsinusoidal wave power source.

10. The rectifier in accordance with claim 6, 7, 8 or 9, wherein the rectifier is configurable to form a half wave rectifier or a full wave rectifier or multivoltage rectifier.
